(19) United States
(12) Patent Application Publication
(10) Pub. No.: US 2003/0151092 A1
(43) Pub. Date: Aug. 14, 2003

(54) Power mosfet device with reduced snap-back and being capable of increasing avalanche-breakdown current endurance, and method of manafacturing the same

(76) Inventor: Feng-Tso Chien, Chung-Li City (TW)

Correspondence Address: Carmody & Torrance LLP, 50 Leavenworth Street, P.O. Box 1110, Waterbury, CT, 06721-1110, US

(21) Appl. No.: 10/073,404

(22) Filed: Feb. 11, 2002

(51) Int. Cl. H01L 29/76; H01L 29/94; H01L 31/062

(52) U.S. Cl. 257/341; 257/336; 257/344; 257/345; 438/268; 438/269

(57) ABSTRACT

The invention disclosed a power MOSFET with reduced snap-back and being capable increasing avalanche-breakdown current endurance, which has sequentially a drain with N⁺ silicon substrate, an N⁻ epitaxial layer formed on said N⁺ silicon substrate, a source contact region formed of N⁺ doped well and P⁺ doped well implanted after etching in a P⁻ well formed on said N⁻ epitaxial layer, and a gate electrode with deposition of polysilicon above a channel between said N⁻ epitaxial layer and N⁺ source contact region, said device is characterized in that: Said source contact region is formed by etching into said P⁻ well first and implanting P⁺ dopant to the interface between said N⁻ epitaxial layer and P⁻ well, and the source contact region of said N⁺ well and that of said P⁺ well are not at the same level, by which it is possible to increase the avalanche-breakdown current endurance of the power MOSFET device.

### FIELD OF THE INVENTION

The present invention relates to a power MOSFET (Metal Oxide Semiconductor Field Effect Transistor) device with reduced snap-back and being capable of increasing avalanche-breakdown current, which can reduce the occurrence of snap-back and being capable of increasing its avalanche-breakdown current endurance and method of manufacturing the same.

### BACKGROUND ART

In FIG. 1(a) to FIG. 1(h), the manufacturing steps of a vertical power MOSFET according to prior arts are shown. FIG. 1(a) shows the step of growing a field oxide 3 on an N⁻ epitaxial layer 2 and said N⁻ epitaxial layer 2 is formed on a N⁺ substrate 1. FIG. 1(b) shows the step of etching said field oxide 3 and performing the growth of gate oxide 4. FIG. 1(c) shows the step of depositing a polysilicon layer 5. FIG. 1(d) shows the step of performing photo masking and etching said polysilicon layer to form a polysilicon gate, and implanting and driving-in P⁻ dopant to form a P⁻ well, i.e. P⁻ channel region 6. FIG. 1(e) shows the step of applying photo mask of P⁺ dopant and implanting P⁺ dopant to form a P⁺ well 7. FIG. 1(f) shows the step of applying photo mask of N⁺ dopant and implanting N⁺ dopant to form the source region 8. FIG. 1(g) shows the step of depositing BPSG (Boro-Phosopho Silicate Glass). FIG. 1(h) shows the step of metallizing said source contact 10 and processing the back contact of wafer to form a drain contact 11. In this power MOSFET device manufactured by prior art, when said device is OFF and there is reverse leakage current flowing in the P⁻ well or P⁻ channel region 6, since said N⁺ and P⁺ wells 8 and 7 are of the same potential (due to the same potential on source) and said P⁻ well is a lightly doped region, said reverse leakage current flows from said N⁻ epitaxial layer 2 and passes through P⁻ well 6 and P⁺ well 7 to source (8,10) and generates a voltage drop in the region between P⁻ well 6 and N⁺ source 8. When said voltage drop is greater than 0.6 to 0.7 volt, a parasitic diode in said device will be turned ON and generates a large amount of reverse leakage current and result in a phenomena of snap-back. Since said large amount of reverse leakage current is generally uniformly concentrated at the turning corner of the interface between P⁻ well 6 and N⁻ epitaxial layer 2, it is thus easy to arise the temperature of said interface (i.e. thermal run-away) and to damage the device. Therefore, the avalanche-breakdown current endurance of such a device is not very well.

Currently the vertical power MOSFET device is broadly used in the power switching power supply circuit, such application has the most serious failure mode in that a large amount of avalanche-breakdown current is generated under the inductive switching and will cause a destructive damage to such device.

U.S. Pat. Nos. 4,774,198, 5,057,884, 4,587,713, and 5,268,586 have disclosed methods of adding a heavily doped P⁺ region in the P⁻ well to lower the probability of parasitic BJT (bipolar junction transistor) ON in said P⁻ well, which prevent said device from being damaged by excess avalanche-breakdown current to increase the avalanche-breakdown current endurance, as shown in FIGS. 3-6. The I-V characteristics of such a device will be described later.

Therefore, it is necessary to design a power MOSFET with reduced snap-back to increase its avalanche-breakdown current endurance, so that it is possible to greatly increase the quality and reliability of such a device, and prevent from variation due to instant unstable power supply in electrical circuit application.

### SUMMARY OF THE INVENTION

Therefore, the object of present invention is to provide a power MOSFET device with reduced snap-back and being capable of increasing avalanche-breakdown current endurance and method of manufacturing the same.

To achieve the above mentioned object of present invention, according to the aspect of the present invention, a power MOSFET device with reduced snap-back and being capable of increasing avalanche-breakdown current endurance is provided, which has sequentially a drain with N⁺ silicon substrate, a N⁻ epitaxial layer formed on said N⁻ silicon substrate, a source contact region formed of N⁺ doped well and P⁺ doped well implanted after etching in a P⁻ well formed on said N⁻ epitaxial layer, and a gate electrode with deposition of polysilicon above a channel between said N⁻ epitaxial layer and N⁺ source contact region, said device is characterized in that: Said source contact region is formed by etching into said P⁻ well first and by implanting P⁺ dopant to the interface between said N⁻ epitaxial layer and P⁻ well, and the source contact region of said N⁺ well and that of said P⁺ well are not at the same level, by which it is possible to increase the avalanche-breakdown current endurance of the power MOSFET device.

According to another aspect of the present invention, a method of manufacturing a power MOSFET device with reduced snap-back and being capable of increasing avalanche-breakdown current endurance is provided, comprising the following steps:

1. An N⁻ epitaxial layer is epitaxially grown on a N⁺ silicon substrate;

2. A field oxide is grown on said N⁻ epitaxial layer;

3. Etching said field oxide, and growing a gate oxide layer;

4. Depositing a polysilicon layer;

5. Performing lithography and then etching said polysilicon layer to form a polysilicon gate, and implanting and driving-in P⁻ dopant to form a P⁻ well;

6. Applying photo mask of P⁺ dopant and implanting P⁺ dopant implantation to form a P⁺ well;

7. Producing a photoresist, and after the source etching region is defined, implanting P⁺ dopant to form a P⁺ well, and subsequently removing the photoresist;

8. Depositing BPSG (Boro-Phosopho Silicate Glass); and

9. Performing metallization of said source contact and processing the back contact of wafer to form a drain contact.

According to the characteristics of a power MOSFET device in present invention, when said device is ON there is electron current flowing from source and passing through the inversed channel region of P⁻ well to N⁻ epitaxial layer and then to N⁺ drain; when said device is OFF there is reverse leakage current flowing from drain via N⁻ epitaxial layer and directly passing through P⁺ well to source, since said P⁺ doped well is heavily doped and has small resistance, it is not easy to create a voltage drop to turn on the parasitic PN diode, thus a large amount of reverse leakage current is generated and a phenomena of snap-back is taken place, and the avalanche-breakdown current endurance of such a device is increased. Further, though it is not easy to place said heavily doped P⁺ well deeply into the interface between said P⁻ well and N⁻ epitaxial layer, according to the manufacturing method of present invention, in the step of implanting P⁺ dopant into said N⁺ source region to form a P⁺ well, said N⁺ source region is etched down for a depth of 1 μm to 1.2 μm (adjustable according to different voltage durable device) into said P⁻ well, and said P⁻ well is implanted with P⁺ dopant to create a P⁺ doped well at the interface between said P⁻ well and N⁻ epitaxial layer.

### BRIEF DESCRIPTION OF DRAWINGS

The above and other objects, features, and advantages of present invention will become more apparent from the following detailed description in conjunction with the accompanying drawings:

FIGS. 1(a) to 1(h) shows the manufacturing steps of a power MOSFET device according to prior art;

FIGS. 2(a) to 2(j) shows the manufacturing steps of a power MOSFET device according to present invention.

FIGS. 3 to 6 shows schematically the structures described in U.S. Pat. Nos. 4,774,198, 5,057,884, 4,587,713, and 5,268,586;

FIGS. 7(a) and 7(b) show schematically the prior art testing circuit and the I-V characteristic diagram of the measurement on the avalanche-breakdown current endurance of the power MOSFET device, respectively;

FIG. 8 shows the avalanche-breakdown current endurance I-V characteristic graph of a MOSFET device in prior art (a simulation graph according to U.S. Pat. No. 4,774,198), wherein though P⁺ dopant is implanted in the source, no etching is performed; and

FIG. 9 shows the avalanche-breakdown current endurance I-V characteristic diagram of a MOSFET device in present invention, wherein the source is etched and implanted with P⁺ dopant.

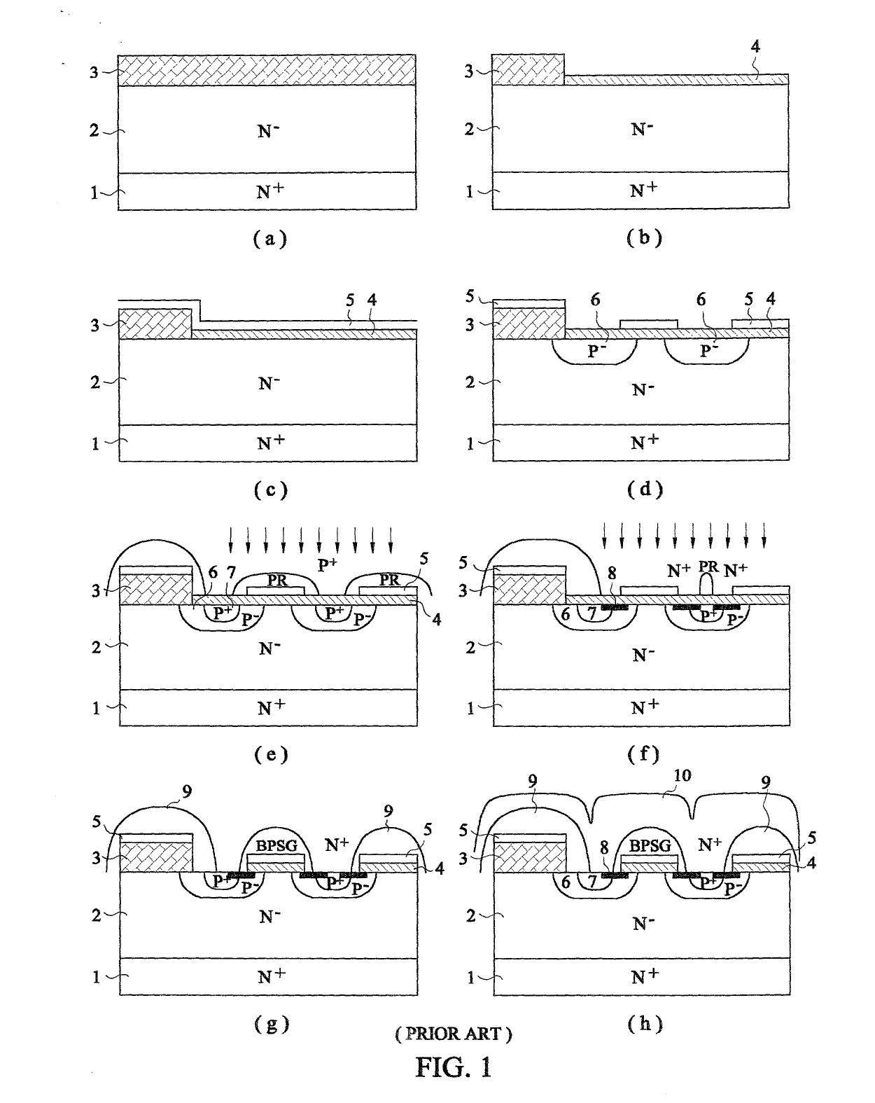

### DETAILED DESCRIPTION OF THE INVENTION

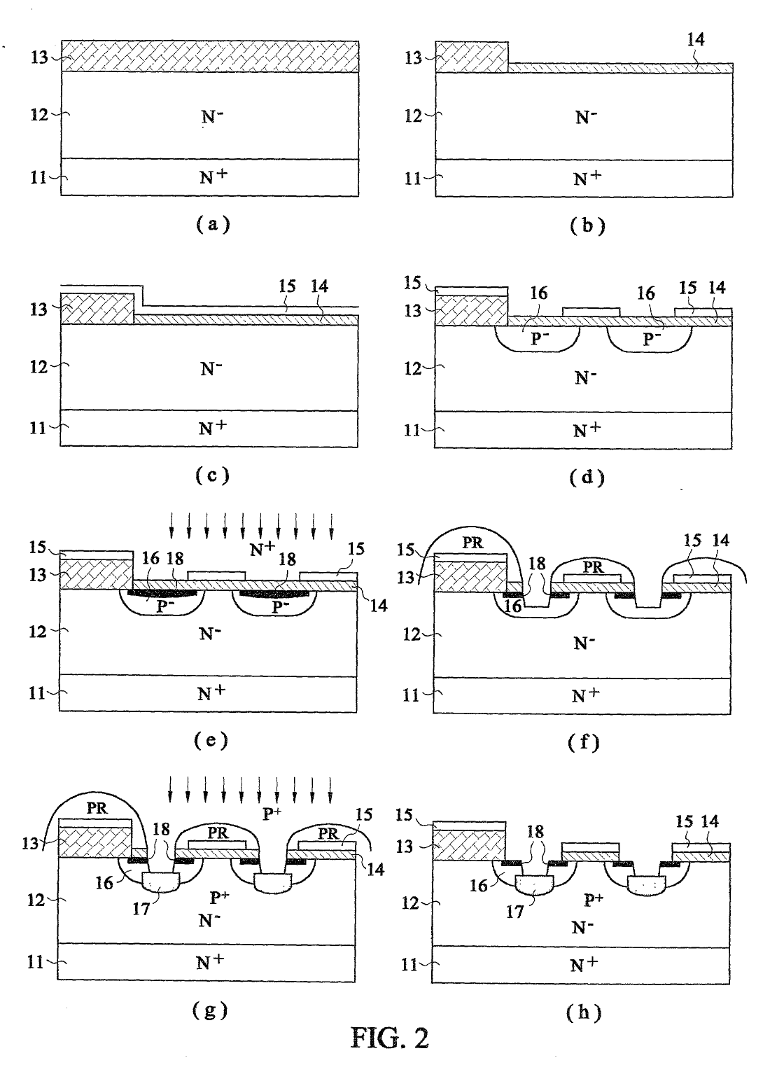

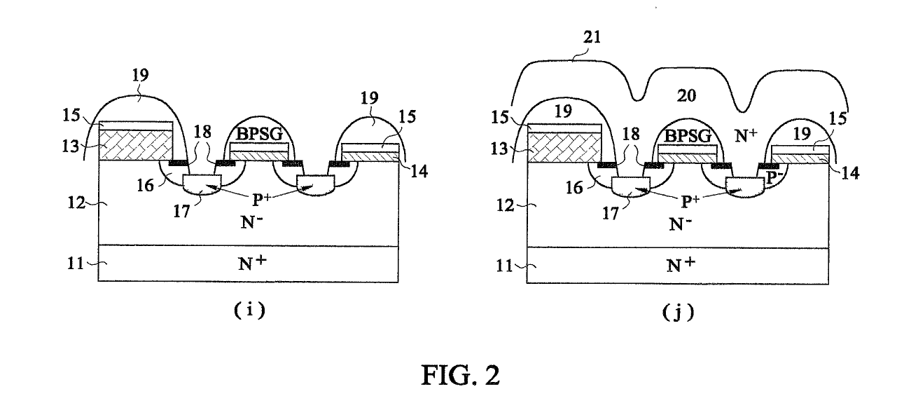

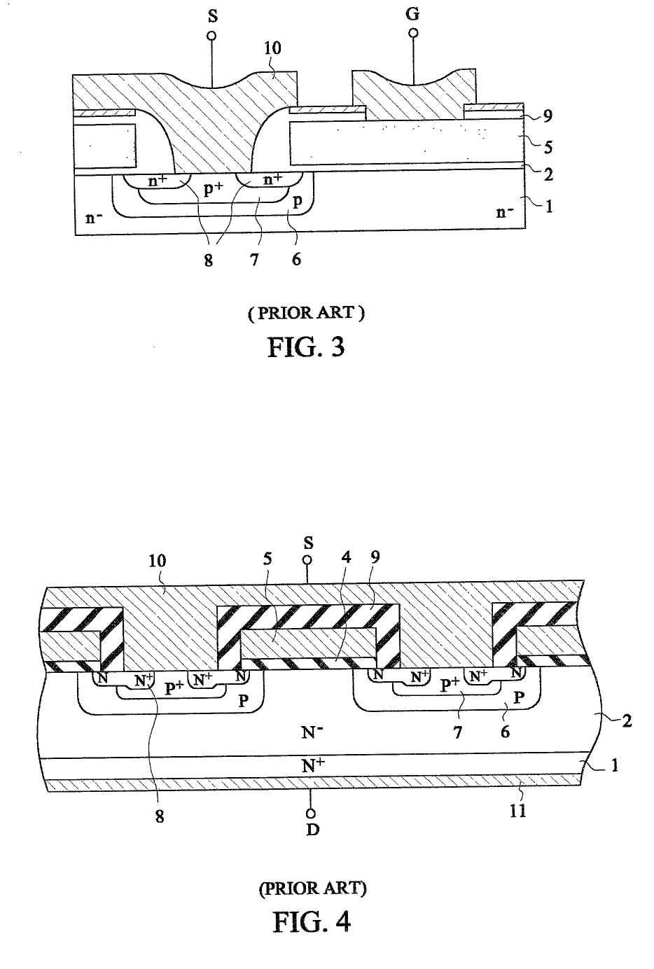

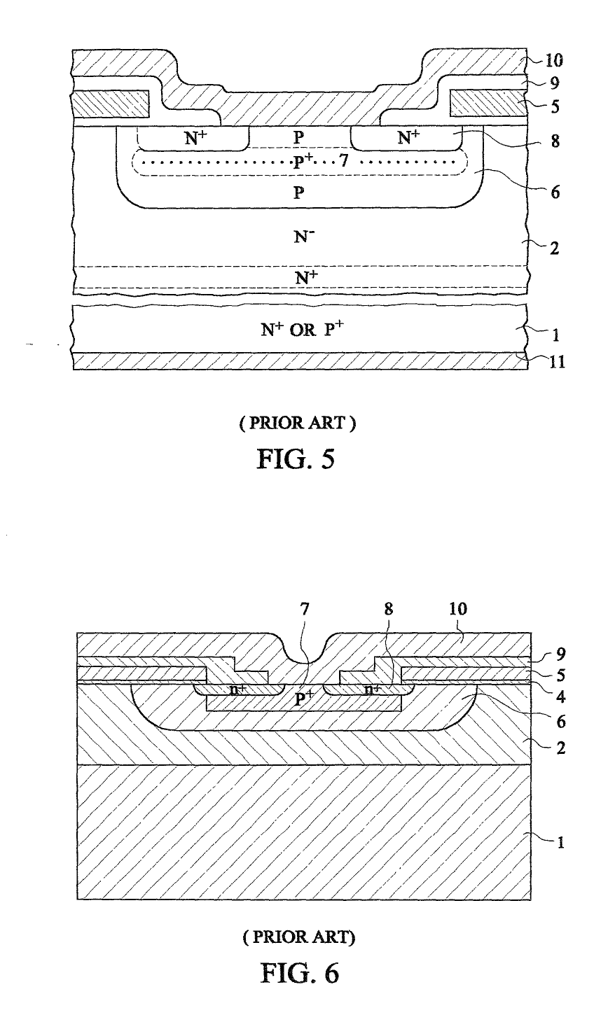

FIGS. 2(a) to 2(h) shows the manufacturing steps of a power MOSFET device according to present invention. FIG. 2(a) shows the step of growing a N⁻ epitaxial layer 2 on N⁻ substrate 11 and growing a field oxide 13 on said N⁻ epitaxial layer 12. FIG. 2(b) shows the step of etching said field oxide 13 and growing a gate oxide layer 14 as the gate dielectric. Next, FIG. 2(c) shows the step of depositing a polysilicon layer 15 on said gate oxide 14. FIG. 2(d) shows the step of performing lithography and etching said polysilicon layer 15 to form a polysilicon gate, and implanting and driving-in P⁻ dopant to form a P⁻ well. FIG. 2(e) shows the step of applying photo mask of N⁺ dopant and implanting N⁺ dopant to form a N⁺ well 8.

Next, FIG. 2(f) shows a step of etching said N⁺ source region down for a depth of 1 μm to 1.2 μm (this depth is adjustable according to different voltage endurance device, here is an exampled 30 V voltage endurance MOSFET device) into said P⁻ well 16, FIG. 2(g) shows the step of the source region of said P⁻ well 16 being implanted with P⁺ dopant to create a P⁺ doped well at the interface between said P⁻ well and N⁻ epitaxial layer, and then said photoresist is removed as shown in FIG. 2(h). FIG. 2(i) shows the step of depositing BPSG (Boro-Phosopho Silicate Glass) 19. FIG. 2(j) shows the step of metallizing said source contact 20 and processing the back metal contact of wafer to form a drain contact, and from a passivation layer 21 on said metal to complete a power MOSFET of the invention. As described above, said device has sequentially a drain with N⁺ silicon substrate 11, an N⁻ epitaxial layer 12 formed on said N⁺ silicon substrate 11 a P⁻ well 16 formed on said N⁻ epitaxial layer 12, a source contact region of N⁺ doped well 18 and P⁺ doped well 17 formed on said P⁻ well 16, and a gate electrode with deposition of polysilicon above a channel between said N⁻ epitaxial layer 12 and N⁺ source contact region 18, wherein the source contact region of said P⁺ doped well 17 is located on the interface between said N⁻ epitaxial layer 12 and said P⁻ well 16, and the source contact region of said N⁺ well 18 and that of said P⁺ well are not at the same level.

According to the device of present invention, when said device is OFF there is reverse leakage current flowing from N⁻ epitaxial layer 12 directly passing through P⁺ well 17 to source contact metal 20, since said P⁺ doped well 17 is heavily doped and has small resistance, it is not easy to create a voltage drop between the source 18 and said P⁻ well 16 to turn on the parasitic PN diode, thus a large amount of reverse leakage current is generated and a phenomena of snap-back is taken place, and the avalanche-breakdown current endurance of such a device is increased.

Further, according to the manufacturing method of the present invention, in the step of implanting P⁺ dopant in said N⁺ source region 18 to form a P⁺ well 17, said N⁺ source region is etched down for a proper depth into said P⁻ well 16, the etching area of said P⁻ well 16 is implanted with P⁺ dopant to create a P⁺ doped well 17 at the interface between said P⁻ well 16 and N⁻ epitaxial layer 12, so that it is possible to overcome the disadvantage of prior art for being not easy to implant a heavily doped layer at a deeper place.

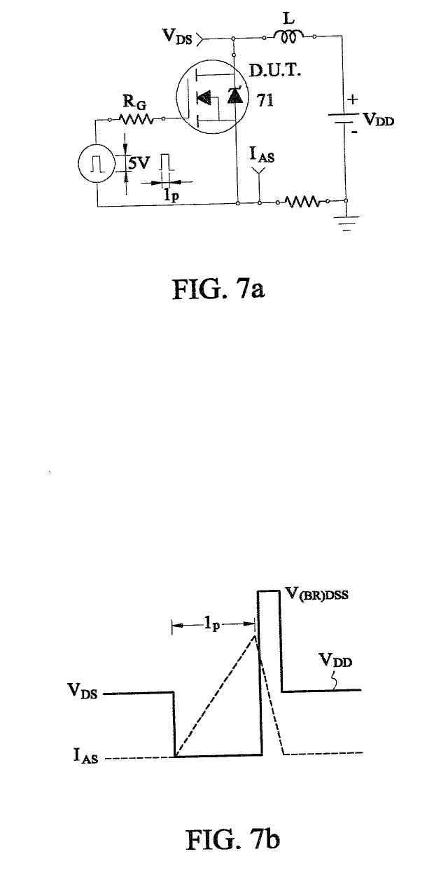

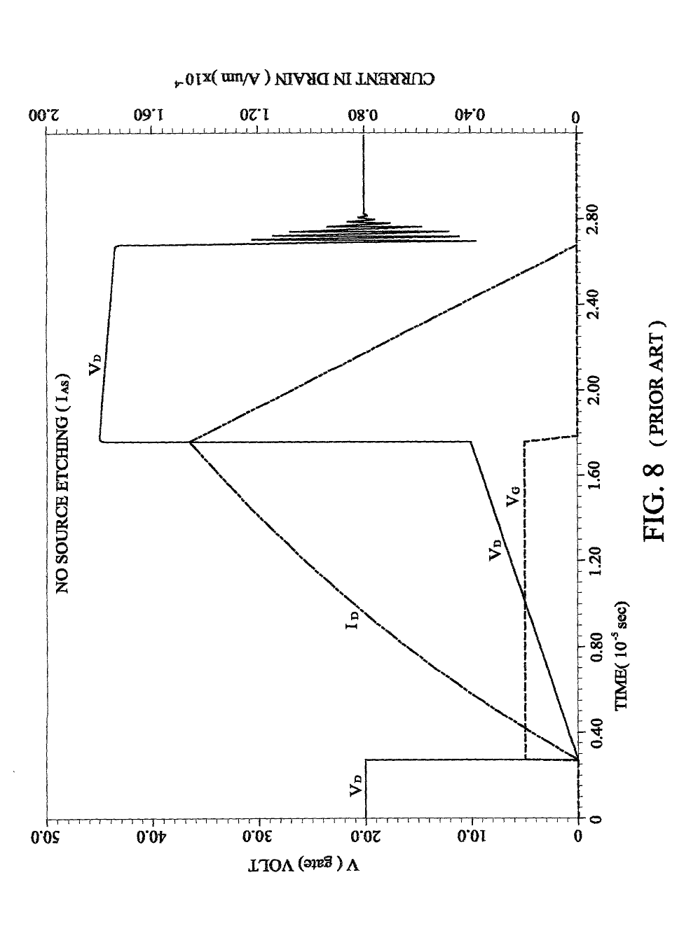

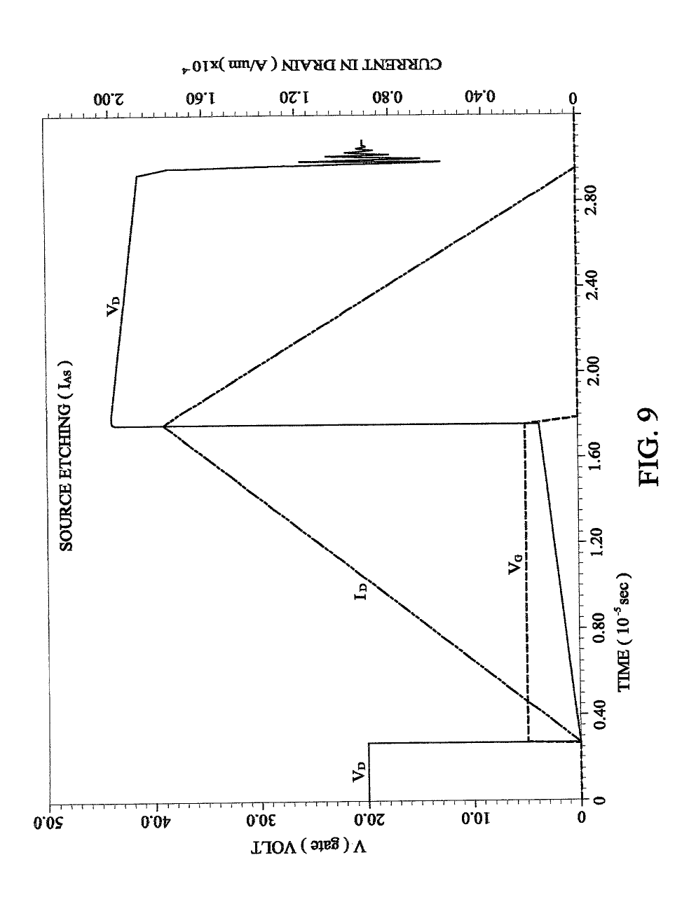

FIGS. 7(a) and 7(b) show schematically the prior testing circuit and the I-V characteristic graph of the measurement on the avalanche-breakdown current endurance of the power MOSFET device 71 (D.U.T.), respectively. The higher the IAS curve in FIG. 7(b) represents better the avalanche-breakdown current endurance of said MOSFET device 71 (D.U.T.). FIG. 8 shows the avalanche-breakdown current durable I-V characteristic graph of a MOSFET device in prior art (e.g., U.S. Pat. No. 4,774,198), wherein though P⁺ dopant is implanted in the source, no etching is performed. FIG. 9 shows the avalanche-breakdown current endurance I-V characteristic graph of a MOSFET device in the present invention, wherein the source is implanted with P⁺ dopant and etching is performed. Both of above two characteristic graphs are simulated from the Avanti MEDICI software simulation. It can be seen from the comparison of above two characteristic graphs that the avalanche-breakdown current endurance of the MOSFET device according to present invention is greatly improved.

Although above description is given in a vertical N-channel power MOSFET device, the present invention is suitable for a vertical P-channel power MOSFET device, all we need to do is replace N with P and P with N. Further, the present invention is also applicable to planar power MOSFET device or IGBT (Insulation Gate Bipolar Transistor). Those who are skilled in this technique will understand that present invention is not limited to above description and is allowed to have various modification and change.

Different manufacturing methods and ion implantation techniques that can result in same device structure as the present invention are considered within the range of the present invention, however, the present invention will be explained by the following claims.

List of Reference Numerals

Numeral Description

1 substrate

2 epitaxial layer

3 field oxide

4 gate oxide

5 polysilicon

6 well, channel region

7 doped well

8 doped well

9 BPSG (Boro-Phosopho Silicate Glass)

10 source metal contact

11 substrate

12 epitaxial layer

13 field oxide

14 gate oxide

15 polysilicon

16 well, channel region

17 doped well

18 doped well

19 BPSG (Boro-Phosopho Silicate Glass)

20 source metal contact

21 passivation layer

71 D.U.T. (Device Under Test, Power MOSFET Device)

What we claimed are:

1. A power MOSFET device with reduced snap-back and being capable of increasing avalanche-breakdown current endurance, which has sequentially a drain with N⁺ silicon substrate, an N⁻ epitaxial layer formed on said N⁺ silicon substrate, a source contact region formed of N⁺ doped well and P⁺ doped well implanted after etching in a P⁻ well formed on said N⁻ epitaxial layer, and a gate electrode with deposition of polysilicon above a channel region between said N⁻ epitaxial layer and N⁺ source contact region, said device is characterized in that: Said source contact region is formed by etching into said P⁻ well first and implanting P⁺ dopant to the interface between said N⁻ epitaxial layer and P⁻ well, and the source contact region of said N⁺ well and that of said P⁺ well are not at the same level, by which it is possible to increase the avalanche-breakdown current durable capability of the power MOSFET device.

2. A method of manufacturing a power MOSFET device with reduced snap-back and being capable increasing avalanche-breakdown current endurance, comprising the following steps:
1. An N⁻ epitaxial layer is epitaxially grown on a N⁺ silicon substrate;
2. A field oxide is grown on said N⁻ epitaxial layer;
3. Etching said field oxide and growing a gate oxide layer;
4. Depositing a polysilicon layer;
5. Performing photo masking and etching said polysilicon layer to form a polysilicon gate, and implanting and driving-in P⁻ dopant to form a P⁻ well;
6. Applying photo mask of N⁺ dopant and implanting N⁺ dopant to form a N⁺ source;
7. Producing a photoresist, and after the source region is etched, implanting P⁺ dopant to form a P⁺ well, and subsequently removing the photoresist;
8. Depositing BPSG (Boro-Phosopho Silicate Glass); and
9. Performing a metalization of said source contact and processing the back contact of wafer to form a drain contact.
